(19) United States
(12) Patent Application Publication
(10) Pub. No.: US 2020/0049762 A1
(43) Pub. Date: Feb. 13, 2020

(54) PROBE APPARATUS, PROBE INSPECTION METHOD, AND STORAGE MEDIUM

(71) Applicant: Tokyo Electron Limited, Tokyo (JP)

(72) Inventors: Tomohiro Ota, Yamanashi (JP); Mitsuyoshi Miyazono, Tokyo (JP); Shinya Koizumi, Yamanashi (JP); Atsushi Ishii, Knagawa (JP); Takashi Tasaki, Osaka (JP)

(21) Appl. No.: 16/532,866

(22) Filed: Aug. 6, 2019

(30) Foreign Application Priority Data
Aug. 7, 2018 (JP) 2018-148735

(51) Int. Cl. G01R 31/28; G01R 1/073; G01R 1/067

(52) U.S. Cl. CPC G01R 31/2891; G01R 1/07342; G01R 1/0675; G01R 1/06794; G01R 1/07364

(57) ABSTRACT

In a probe apparatus for performing an electrical measurement by bringing a probe into contact with an inspection target substrate, a transfer table is provided with a needle mark transfer member to which a needle mark of the probe is transferred by a contact with the probe. The needle mark transfer member includes a polyimide resin. A movement mechanism is able to move the needle mark transfer member provided on the transfer table to a contact position where the needle mark transfer member is brought into contact with the probe.

### CROSS-REFERENCE TO RELATED APPLICATIONS

The present application is based on and claims priority from Japanese Patent Application No. 2018-148735, filed on Aug. 7, 2018, with the Japan Patent Office, the disclosure of which is incorporated herein in its entirety by reference.

### TECHNICAL FIELD

The present disclosure relates to a technology of inspecting a probe that performs an electrical measurement of an integrated circuit (IC).

### BACKGROUND

In a process of manufacturing a semiconductor device, a probe test is performed after ICs are formed on the surface of a semiconductor wafer (hereinafter, referred to as a “wafer”), to measure an electrical characteristic of each IC in a state where the IC chip is not separated from the wafer (in this case, the wafer corresponds to an inspection target substrate) or in a state where the separated IC chip is placed in a dedicated inspection target substrate.

The probe test is performed using, for example, a probe card provided with a number of probes, and carried out by firmly pressing the inspection target substrate against the probe card such that an electrode pad of an IC to be inspected is brought into contact with the probes, and inputting/outputting inspection electric signals.

In the probe test described above, in order to accurately contact an electrode pad of each IC in the inspection target substrate with the probes of the probe card, it is necessary to accurately grasp the position of the electrode pad of each IC and the positions of the probes of the probe card, and perform an alignment for aligning the positions of the electrode pad and the probes.

In order to perform the alignment, as a method of grasping the positions of the respective probes of the probe card, there is a known method of firmly pressing the probe card against a needle mark transfer sheet (a needle mark transfer member) made of a resin and deforming the portions of the resin that are brought into contact with the probes so as to transfer needle marks. By, for example, capturing an image of the needle mark transfer sheet to which the needle marks have been transferred, information of the arrangement position of the probes or the like may be acquired.

For example, Japanese Patent Laid-open Publication No. 2011-049261 (Claim 1 and paragraph [0040]) describes a technology of transferring needle marks by bringing the probes into contact with a monofunctional (meth) acrylate.

### SUMMARY

An embodiment of the present disclosure provides a probe apparatus for performing an electrical measurement by bringing a probe provided on a probe card into contact with a substrate placed on a placement table, the probe apparatus including: a transfer table provided with a needle mark transfer member to which a needle mark of the probe is transferred and configured to bring the probe into contact with the needle mark transfer member, instead of bringing the probe into contact with the substrate; and a mover configured to move an arrangement position of at least one of the transfer table and the probe card between a contact position where the needle mark transfer member is brought into contact with the probe and a separation position where the needle mark transfer member is separated from the contact position, the needle mark transfer member including a polyimide resin

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a vertical cross-sectional side view illustrating a probe apparatus according to an embodiment.

FIG. 2 is a configuration diagram of a needle mark transfer mechanism provided in the probe apparatus.

FIG. 3 is an explanatory view illustrating a temperature characteristic of a polyimide resin such as a storage elastic modulus.

FIG. 4 is an explanatory view illustrating a relationship between an addition of a plasticizer and a change in characteristic.

FIG. 5 is a first operation view of the probe apparatus.

FIG. 6 is a second operation view of the probe apparatus.

FIG. 7 is an explanatory view illustrating a temperature characteristic of an epoxy resin such as a storage elastic modulus.

FIGS. 8A and 8B are captured image views according to a needle mark transfer of cantilever type probes.

FIGS. 9A and 9B are captured image views according to a needle mark transfer of probes with tips formed by vertical square needles.

FIGS. 10A and 10B are captured image views according to a needle mark transfer of probes formed by pogo pins.

FIG. 11 is a captured image view according to a needle mark transfer of probes formed by cobra-pins.

### DETAILED DESCRIPTION OF THE DRAWINGS

In the following detailed description, reference is made to the accompanying drawings, which form a part thereof. The illustrative embodiments described in the detailed description, drawings, and claims are not meant to be limiting. Other embodiments may be utilized, and other changes may be made without departing from the spirit or scope of the subject matter presented here.

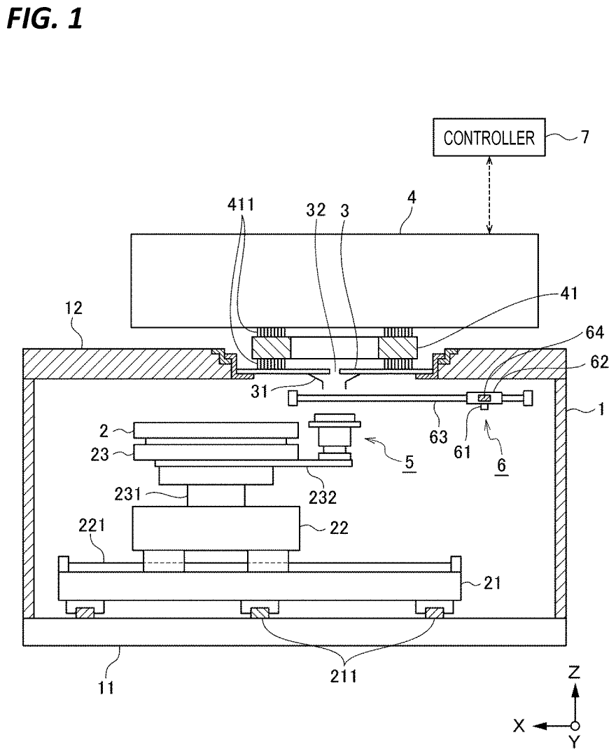

First, an entire configuration of a probe apparatus according to an embodiment will be described with reference to FIG. 1, etc.

As illustrated in FIG. 1, the probe apparatus includes a housing body 1 that constitutes the main body of the apparatus. On a base mount 11 of the bottom of the housing body 1, a Y stage 21 and an X stage 22 are provided in this order from the bottom of the housing body 1. The Y stage 21 is configured to be movable along Y rails 211 that extend in the Y direction (the direction orthogonal to the plane of FIG. 1), and the X stage 22 is configured to be movable along X rails 221 that extend in the X direction (the left-and-right direction of FIG. 1 when viewed from the front).

For example, the Y stage 21 or the X stage 22 is provided with a ball screw or a linear motor mechanism (not illustrated), and the stop position of the Y stage 21 in the Y direction and the stop position of the X stage 22 in the X direction may be accurately adjusted using a motor with which an encoder or a linear scale is combined.

A Z movement unit 23 is provided on the X stage 22 to be supported by a telescopic shaft 231 configured to be telescopic, and is configured to be movable up and down in the Z direction (the vertical direction). Further, a wafer chuck 2 is provided on the side of the upper surface of the Z movement unit 23 and configured to be rotatable about the Z axis on the Z movement unit 23 (movable in the θ direction). The movement amount in the Z direction and the rotation amount of the wafer chuck 2 may also be accurately grasped by an encoder.

The above-described Y stage 21, X stage 22, and Z movement unit 23 constitute a wafer movement mechanism, and may move the wafer chuck 2 in each of the X, Y, Z, and θ directions.

The upper surface of the wafer chuck 2 serves as a placement surface for placing a wafer with inspection target ICs thereon, and holds the wafer by an adsorption. The wafer chuck 2 corresponds to a placement table of the present embodiment.

When an area where the wafer chuck 2 (the wafer placed on the placement surface) moves by the action of the Y stage 21, the X stage 22, and the Z movement unit 23 is referred to as a movement area, a probe card 3 is provided above the movement area. The probe card 3 is detachably mounted in a head plate 12 which is a top plate of the housing body 1.

The probe card 3 is configured as a printed circuit board (PCB), and a group of electrodes (not illustrated) is formed on the upper surface of the probe card 3. Further, an intermediate ring 41 is interposed between a test head 4 disposed above the head plate 12 and the probe card 3, to establish an electric conduction between terminals of the test head 4 and the group of electrodes described above.

The intermediate ring 41 is configured as a pogo pin unit provided with a number of pogo pins 411 which serve as electrode portions, to correspond to the arrangement position of the group of electrodes of the probe card 3. For example, the intermediate ring 41 is fixed to the side of the test head 4.

In addition, the test head 4 is configured to be rotatable around the horizontal rotation axis by a hinge mechanism (not illustrated) provided beside the housing body 1. With this configuration, the test head 4 may be rotatably movable between a measurement position where the test head 4 holds the intermediate ring 41 horizontally to bring the respective pogo pins 411 into a state being in contact with the group of electrodes of the probe card 3 (FIG. 1), and a retraction position where the test head 4 separates the intermediate ring 41 from the probe card 3 and holds the intermediate ring 41 in a state where the bottom surface thereof faces upward (not illustrated).

In addition, the test head 4 includes a data storage (not illustrated) that stores, as inspection data, an electric signal indicating an electric characteristic of an IC which is measured via the probe card 3, and a determination unit (not illustrated) that determines a presence/absence of an electrical defect in the inspection target IC based on the inspection data.

A number of probes 31 are provided on the lower surface of the probe card 3 to be electrically connected to the group of electrodes, respectively, on the upper surface of the probe card 3. FIGS. 1, 5, and 6 schematically illustrate an example where each probe 31 is configured by a conductive metal called a cantilever or a side gauge (FIGS. 1, 5, and 6 illustrate only two cantilever probes 31, for the convenience of illustration). Each probe 31 is provided on the lower surface of the probe card 3 to project obliquely downward with the tip thereof directed toward a rectangular opening 32 formed in the center of the probe card 3.

In addition, as represented in experiment results of Examples to be described later, the probe 31 may be configured by, for example, a vertical needle that extends vertically downward from the lower surface of the probe card 3, a pogo pin of which tip is capable of projecting from/retracting into the pin body, or a cobra pin provided with a curved portion in the middle of the pin body such that the tip of the pin is movable up and down when the pin is brought into contact with an electrode pad of an IC.

The probe apparatus having the configuration described above grasps the arrangement position of each probe 31 using a transfer mechanism 5 and an image capturing unit 6, in performing the alignment work described above.

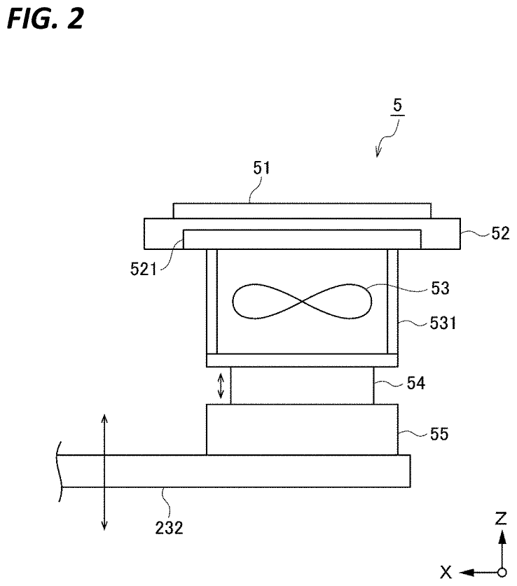

Hereinafter, a configuration of the transfer mechanism 5 will be described with reference to FIGS. 2 to 4.

As illustrated in FIGS. 1 and 2, the transfer mechanism 5 is provided with a needle mark transfer sheet (a needle mark transfer member) 51 to which needle marks are transferred by a contact with the probes 31. The needle mark transfer sheet 51 is placed on the upper surface of a transfer table 52, and the transfer table 52 is supported by a support arm 232 via a transfer table support 54 and a base mount 55.

The support arm 232 is provided on the upper end of the telescopic shaft 231 together with the Z movement unit 23 described above, and is movable in the Y, X, and Z directions by the action of the Y stage 21, X stage 22, and the telescopic shaft 231. The Y stage 21, the X stage 22, and the telescopic shaft 231 function as a movement mechanism that moves the needle mark transfer sheet 51 (the transfer mechanism 5).

A Peltier element 521 is disposed inside the transfer table 52. The Peltier element 521 may switch the surface thereof in contact with the transfer table 52 to a heating surface or a cooling surface.

When the surface in contact with the transfer table 52 is set as the heating surface, and the needle mark transfer sheet 51 placed on the transfer table 52 is heated to a preset temperature, the transfer table 52 functions as a heater. In addition, when the surface in contact with the transfer table 52 is set as the cooling surface, and the needle mark transfer sheet 51 placed on the transfer table 52 is cooled to a preset temperature, the transfer table 52 functions as a cooler.

The heating temperature and the cooling temperature of the needle mark transfer sheet 51 will be described later with descriptions of a material of the needle mark transfer sheet 51.

A fan housing 531 is provided between the needle mark transfer sheet 51 and a fan 53, and has a frame body structure that houses the fan (cooling unit) 53. The fan 53 has a function to cool the heat radiation surface of the Peltier element 521 of which the surface in contact with the transfer table 52 is set as the cooling surface, or a function of a cooler to cool the body of the transfer table 52 heated by the Peltier element 521.

The needle mark transfer sheet 51 is a member that is placed on the upper surface of the transfer table 52 and made of a flat sheet-shaped polyimide resin with a thickness of about several hundred micrometers to several millimeters. When the needle mark transfer sheet 51 has a structure in which multiple types of resins are laminated, at least the upper surface of the needle mark transfer sheet 51 which is brought into contact with the probes 31 is made of a polyimide resin. The needle mark transfer sheet 51 placed on the transfer table 52 has the area with which the tips of all the probes 31 provided on the probe card 3 may be contacted.

The transfer table 52 holds the needle mark transfer sheet 51 at a height position where the upper surface of the wafer placed on the wafer chuck 2 and the upper surface of the needle mark transfer sheet 51 have the same height.

As for the polyimide resin used for the needle mark transfer sheet 51, a known polyimide resin of related art (e.g., a polyimide resin obtained by adding a plasticizer to a solvent-soluble polyimide resin and processing the polyimide resin to be in a sheet form) may be used.

Appropriately, when the temperature of the wafer at the time of measuring an electrical characteristic of an IC is T_{S} [° C.], it is preferable to select a polyimide resin of which a peak temperature T_{P} at which a temperature characteristic of a loss tangent (hereinafter, also referred to as “tan δ”) peaks (becomes maximum) falls within a range of T_{S}±10° C.

Here, tan δ[−] is a ratio of a loss elastic modulus E″ [Pa] of a sample to a storage elastic modulus E′ [Pa] which are measured using a known dynamic viscoelasticity measuring device, and is obtained by the following Equation (1).

tan δ=E″/E′ (1)

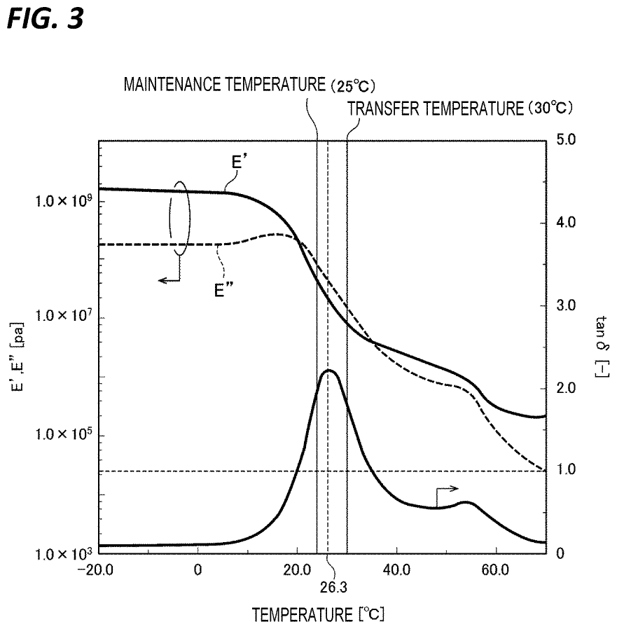

FIG. 3 illustrates changes of values of the storage elastic modulus E′, the loss elastic modulus E″, and the tan δ according to a change in temperature (temperature characteristic), with respect to the polyimide resin used in the Examples to be described later. In FIG. 3, the horizontal axis indicates the temperature of the polyimide resin [° C.], the left vertical axis indicates a value of the storage elastic modulus E′ or the loss elastic modulus E, and the right vertical axis indicates a value of the tan δ.

As illustrated in FIG. 3, the values of the storage elastic modulus E and the loss elastic modulus E of the polyimide resin are substantially constant in a low temperature region, but gradually decrease from around the room temperature (approximately 20° C.).

Accordingly, the polyimide resin is hard in the low temperature region (the storage elastic modulus E′ is high), so that it is difficult to transfer needle marks by the contact with the probes 31. However, once needle marks are formed, a state where the indentation is formed may be maintained. Meanwhile, while the polyimide resin is soft (the storage elastic modulus E is low) in the high temperature region so that needle marks are easily formed by the contact with the probes 31, the formed needle marks may easily disappear in a short time.

In other words, when the temperature is excessively low, it is difficult to transfer needle marks to the polyimide resin even by bringing the probes 31 into contact with the polyimide resin, and when the temperature is excessively high, transferred needle marks immediately disappear, and thus, the needle marks may not be maintained until a timing for performing a position detection to be described later.

With regard to the polyimide resin having the characteristic described above, the inventors of the present disclosure have paid attention to the value of the tan δ described above, and devised a technique of controlling a temperature and transferring and maintaining needles marks.

That is, in a region where the tan δ (=E″/E′)>1.0, more preferably, in a region where the tan δ≥1.5, the influence of the loss elastic modulus E is large, and it is easy to transfer needle marks. Further, it has been found through experiments that in the region described above, transferred needle marks are easily maintained, and an appropriate thermo-plasticity is obtained, only by slightly lowering the temperature of the polyimide resin.

Accordingly, by adopting the polyimide resin having the peak temperature T_{P} of the tan δ that falls within the range of ±10° C. of the temperature T_{S} of the wafer at the time of measuring an electrical characteristic of an IC, needle marks may be transferred and maintained under the substantially same temperature condition as that at the time of using the probes 31.

Here, in the epoxy resin that has been actually used as a material of the needle mark transfer sheet of the related art, it is difficult to transfer needle marks of the probes 31 unless the temperature of the needle mark transfer sheet is raised to around 100° C.

Meanwhile, an electrical characteristic of an IC may be measured under a temperature condition selected from a wide temperature range from sub-zero to 100° C. or more. Thus, for example, when an electrical characteristic is measured at around the room temperature of 15° C. to 35° C., the temperature condition at the time of using the probes 31 and the temperature condition at the time of transferring needle marks may become largely different from each other which causes a thermal expansion of the probes 31, etc., and thus, it may become difficult to accurately grasp the positions of the probes 31.

Meanwhile, in the polyimide resin illustrated in FIG. 3, since the peak temperature T_{P} of the tan δ is 26.3° C., the polyimide resin is brought into contact with the probes 31 under the room temperature (e.g., 23° C.), so that there is an effect in that it is difficult to cause the temperature influence to the state of the probes being under a low or high temperature.

In addition, the peak temperature T_{P} of the tan δ may be adjusted by adding a plasticizer to the polyimide resin.

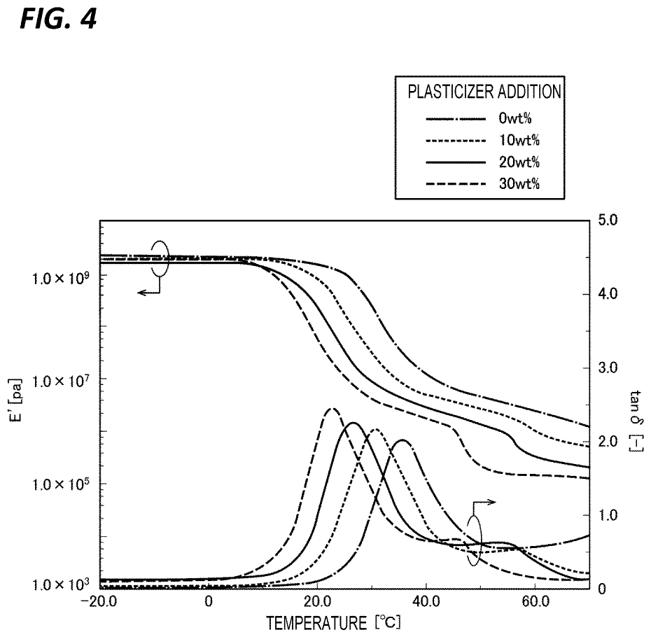

FIG. 4 illustrates the temperature characteristics of the storage elastic modulus E′ and the tan δ when an addition amount of a plasticizer (a phosphazene derivative in the present example) is changed to 0 wt %, 10 wt %, 20 wt %, and 30 wt %, for the same polyimide resin as that illustrated in FIG. 3.

According to FIG. 4, as the addition amount of the plasticizer is increased, the temperature at which the storage elastic modulus E starts to decrease is lowered, and with this tendency, the peak temperature T_{P} of the tan δ is also gradually lowered.

FIG. 3 illustrates the characteristic of the polyimide resin when the addition amount of the plasticizer is 20 wt % in FIG. 4.

As described above, when the peak temperature of the tan δ of the polyimide resin to which the plasticizer is not added is higher than the temperature T_{S} of the wafer at the time of measuring an electrical characteristic of an IC, the addition amount of the plasticizer may be adjusted, so as to adjust the peak temperature T_{P} of the tan δ of the polyimide resin used for the needle mark transfer sheet 51 to fall within the range of T_{S}±10° C.

Despite of a change depending on the peak temperature of the tan δ when no plasticizer is added or the maximum addible amount of the plasticizer, it may be said that the polyimide resin is a material suitable for transferring needle marks of the probes 31 when the wafer temperature T_{S} at the time of measuring an electrical characteristic of an IC falls within the range of 15° C. to 35° C.

Here, the plasticizer which is added to the polyimide resin so as to adjust the peak temperature T_{P} of the tan δ is not limited to the example of the phosphazene derivative, and any modifier may be used as long as the modifier may exhibit the action to change the peak temperature T_{P}.

When the polyimide resin that constitutes the needle mark transfer sheet 51 is selected based on the idea described above, a temperature for bringing the probes 31 into contact with the needle mark transfer sheet 51 to transfer needle marks (transfer temperature) and a temperature for maintaining the transferred needle marks (maintenance temperature) are determined.

In the example illustrated in FIG. 3, when the peak temperature T_{P} of the tan δ of the polyimide resin used for the needle mark transfer sheet 51 is 26.3° C., a transfer temperature t is set to 30° C. which falls within a range of T_{P}<t≤T_{P}+5° C. In addition, a maintenance temperature t′ is set to 25° C. which falls within a range of T_{P}−5° C.<t′<T_{P}.

The Peltier element 521 provided in the transfer table 52 performs a heating such that the temperature of the needle mark transfer sheet 51 placed on the transfer table 52 becomes the transfer temperature t described above, and performs a cooling such that the temperature of the needle mark transfer sheet 51 after the transfer of needle marks becomes the maintenance temperature

In this way, by setting the transfer temperature t and the maintenance temperature t′ such that the peak temperature of the tan δ falls between the temperatures t and the temperatures t and t′ may be set to be separated from each other as possible in the region where the value of the tan δ is relatively high (e.g., the region where the value of the tan δ is larger than 1.0). As a result, needle marks may be transferred at the temperature t at which the polyimide resin is more easily deformed, and a state where needle marks are formed on the needle mark transfer sheet 51 may be maintained by slightly adjusting the temperature (cooling), as compared with a case where a cooling is performed to a temperature region where the storage elastic modulus E′ becomes flat.

Further, the probe apparatus of the present embodiment includes an image capturing unit 6 that captures images of needle marks transferred to the needle mark transfer sheet 51 and an electrode pad of an IC formed on the wafer placed on the wafer chuck 2.

For example, the image capturing unit 6 includes a charge-coupled device (CCD) camera 61, a main body 62 of the CCD camera 61, two traveling rails 63 that are disposed to extend in parallel with each other in the lateral direction along the opposing inner wall surfaces of the housing body 1, and a support rod 64 that supports the CCD camera 61 in a state of being stretched between the two traveling rails 63 and is connected to a slider (not illustrated) traveling on the traveling rails 63.

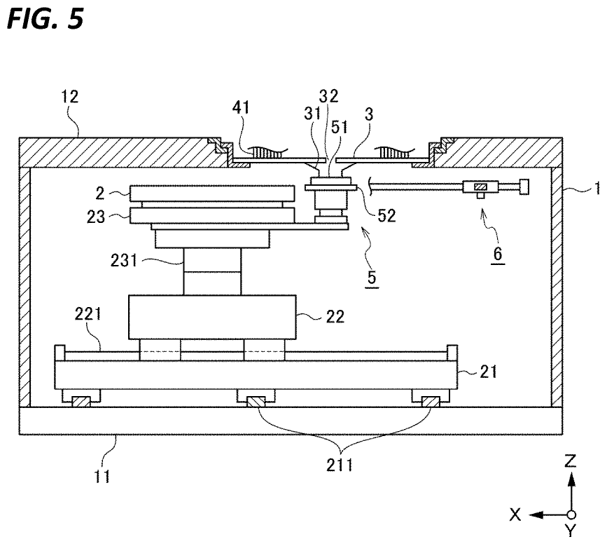

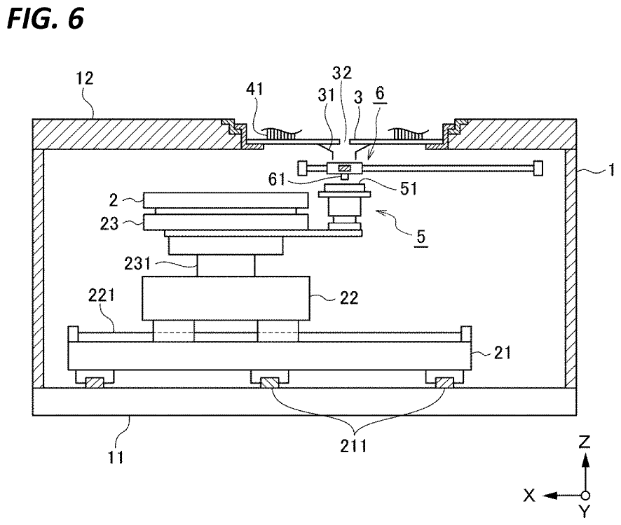

The CCD camera 61 is movable in the lateral direction between an image capturing position where the CCD camera 61 enters the lower side of the probes 31 (see FIG. 6) and a retraction position where the CCD camera 61 retracts from the image capturing position (see FIGS. 1 and 5).

When the CCD camera 61 enters the image capturing position, and the needle mark transfer sheet 51 is positioned below the CCD camera 61, an image of the needle marks transferred to the needle mark transfer sheet 51 is captured. In addition, when the wafer is positioned below the CCD camera 61 positioned at the image capturing position, an image of an electrode pad of an IC is captured.

The probe apparatus having the configuration described above is provided with a controller 7. The controller 7 includes a program, a memory, a data processor including a CPU, etc., and the program is organized with a group of steps for performing an operation to transfer needle marks of the probes 31 to the needle mark transfer sheet 51, an operation to capture an image of the needle marks transferred to the needle mark transfer sheet 51 or an electrode pad of an IC formed on the wafer, and an operation to inspect the wafer after performing the alignment according to the positions of the probes 31 or the electrode pad which are obtained from the image capturing result, by transmitting control signals from the controller 7 to each unit of the probe apparatus. This program is stored in a storage (not illustrated) such as a computer storage medium, for example, a flexible disk, a compact disk, a magneto-optical disk (MO) or the like, and installed in the controller 7.

In addition, the above-described data storage and determination unit which are provided in the test head 4 also constitute a portion of the controller 7.

Hereinafter, an operation to inspect the probes 31 by the probe apparatus of the present embodiment will be described with reference to FIGS. 5 and 6.

First, a probe detection mechanism (not illustrated) is moved to the lower side of the probes 31 using the movement mechanism (the Y stage 21 and the X stage 22). Then, the probe detection mechanism is lifted by the telescopic shaft 231 to detect the height position of the probes 31.

After the height position of the tips of the probes 31 is detected, the Peltier element 521 heats the needle mark transfer sheet 51 to the transfer temperature t (30° C. in the example of the polyimide resin illustrated in FIG. 3). Further, a pressing force of a pressing mechanism inside the base mount 55 is increased to suppress the needle mark transfer sheet 51 from moving downward due to the contact with the probes 31.

When the needle mark transfer sheet 51 has a thickness of about several hundred micrometers, the heat capacity of the needle mark transfer sheet 51 is sufficiently small, and the heat transfer rate thereof is also sufficiently fast. Thus, the temperature control may be performed by regarding the measurement result of the temperature of the transfer table 52 as the temperature of the needle mark transfer sheet 51.

When the needle mark transfer sheet 51 is heated to the transfer temperature, the needle mark transfer sheet 51 is lifted to the height position at which the transfer of needle marks is performed (a contact position: the height position at which the upper surface of the wafer placed on the wafer chuck 2 and the upper surface of the needle mark transfer sheet 51 are the same) to bring each probe 31 into contact with the needle mark transfer sheet 51 (FIG. 5). After the contact state is maintained for about several hundred milliseconds to several seconds, the needle mark transfer sheet 51 is lowered to the position at which an image of the transferred needle marks is captured (a separation position), and the Peltier element 521 cools the needle mark transfer sheet 51 to the maintenance temperature t′ (25° C. in the example of the polyimide resin illustrated in FIG. 3).

By suppressing the difference between the transfer temperature t and the maintenance temperature t′ to be within, for example, 10° C., a rapid temperature adjustment becomes possible, and a state where clear needle marks are transferred to the surface of the needle mark transfer sheet 51 may be maintained. In addition, the cooling of the needle mark transfer sheet 51 may be started before the lowering of the needle mark transfer sheet 51 is started.

Next, the CCD camera 61 enters the image capturing position to capture an image of the needle marks transferred to the needle mark transfer sheet 51 (FIG. 6). At this time, when all of the needle marks formed by the plurality of probes 31 do not appear in the view field of the CCD camera 61, the transfer mechanism 5 is moved in the X and Y directions with respect to the CCD camera 61 to perform the image capturing multiple times. Then, for the position where each image capturing is performed, the amount of the movement in the X and Y directions is grasped by an encoder or a linear scale, so that a position where each needle mark is formed within the plane of the needle mark transfer sheet 51 may be specified with respect to a predetermined reference position.

Based on the image data obtained by each image capturing, a defect, a damage or the like of the probes 31 is detected from the shapes of the needle marks in the image data. Further, the arrangement position of the tip of each probe 31 is detected from each position where a needle mark is formed within the needle mark transfer sheet 51.

Meanwhile, when there is a defect⋅damage, a positional deviation or the like of the probes 31, alarm information or the like is output to a monitor screen to notify an operator of the occurrence of the event.

When no defect⋅damage or positional deviation of the probes 31 is detected, the wafer is carried into the housing body 1 to become a state where the inspection of an IC may be started.

Meanwhile, the needle mark transfer sheet 51 that has been subjected to the image capturing is heated to a temperature sufficiently higher than the transfer temperature, for example, 70° C., so as to erase the needle marks transferred to the needle mark transfer sheet 51. Then, the needle mark transfer sheet 51 stands by in a state of being cooled to, for example, the room temperature using the Peltier element 521 and the fan 53.

When the inspection of the probes 31 is ended in this way such that the inspection of the wafer may be performed, the wafer is carried into the housing body 1 by an external conveyance arm (not illustrated), and placed on the wafer chuck 2. Then, the image capturing unit 6 described above enters the image capturing position to capture an image of an electrode pad of each IC and detect the position thereof.

Then, based on the arrangement position of the probes 31 that is acquired in advance based on the result of the transfer of needle marks to the needle mark transfer sheet 51 and the result of the detection of the position where the electrode pad of each IC formed on the carried-in wafer is formed, the alignment of the wafer chuck 2 in the X, Y, and 0 directions is performed so as to cause the probes 31 to be accurately contacted with the electrode pads. Then, the wafer chuck 2 is lifted by the telescopic shaft 231, the aligned wafer is pressed against the probe card 3, and the electrode pad of a predetermined IC is brought into contact with the probes 31, so as to measure the electrical characteristic.

Then, the wafer chuck 2 (wafer) is sequentially moved with respect to the probe card 3 using the movement mechanism, and the same operation as described above is repeated on the electrode pad of each of the multiple ICs formed on the wafer to perform the inspection.

When the inspection of all of the ICs on the wafer is ended in this way, the wafer chuck 2 is moved to the initial position, the inspected wafer is carried out by an external conveyance arm, and the next wafer is placed on the wafer chuck 2. The inspection of the probes 31 using the needle mark transfer sheet 51 may be performed before the carry-in of each wafer or may be performed each time a preset number of wafers are inspected.

The probe apparatus according to the present embodiment has the following effect. Since the needle mark transfer sheet 51 to which needle marks are transferred by the contact with the probes 31 is made of the polyimide resin, clear needle marks may be transferred.

Here, in the example described above with reference to FIG. 3, the transfer temperature t and the maintenance temperature t′ are set such that the peak temperature T_{P} of the tan δ of the polyimide resin constituting the needle mark transfer sheet 51 falls between the temperature t and t′ (where t>T_{P} and t′<T_{P}), and are set to fall within the temperature range of ±5° C. However, the setting of the transfer temperature or the maintenance temperature is not limited to this example. The transfer temperature may be set to be lower than the peak temperature of the tan δ as long as the transfer of needle marks is possible, and the maintenance temperature may be set to be higher than the peak temperature as long as the maintenance of needle marks is possible.

In addition, it may not be necessarily performed to adjust the peak temperature of the polyimide resin to be within the range of T_{S}±10° C. (where Ts is the temperature of the wafer at the time of measuring an electrical characteristic of an IC) by using the plasticizer. When the positions of the probes 31 may be accurately detected even though the difference between T_{S} and the temperature of the needle mark transfer sheet 51 is large, the needle mark transfer sheet 51 may be constituted by the polyimide resin in which the difference between T_{S} and the peak temperature of the tan δ is 10° C. or higher.

In addition, the heating and the cooling of the needle mark transfer sheet 51 may not be necessarily performed, and when needle marks of the probes 31 may be transferred and maintained at the atmospheric temperature inside the housing body 1 of the probe apparatus, the heater and the cooler such as the Peltier element 521 and the fan 53 may not be provided.

In addition, in the probe apparatus illustrated in FIG. 1, etc., the movement mechanism of the transfer mechanism 5 (the Y stage 21, the X stage 22, and the telescopic shaft 231) is also used as the movement mechanism of the wafer chuck 2. However, each of the transfer mechanism 5 and the wafer chuck 2 may be provided with its own movement mechanism. In addition, as for a technique of moving the transfer mechanism 5 and the probe card 3 relative to each other between the contact position and the separation position, a mechanism may be provided to lower the probe card 3 with respect to the transfer mechanism 5 of which height position is fixed.

In addition, an IC which is subjected to the measurement of an electrical characteristic using the probe apparatus of the present embodiment is not limited to an IC formed on the wafer, and may be an IC which is separated from the wafer, packaged, and mounted on a dedicated inspection target substrate.

### EXAMPLES

(Experiment)

The needle mark transfer sheet 51 made of the polyimide resin and the needle mark transfer sheet 51 made of the epoxy resin were brought into contact with the probes 31, and the difference in transfer of needle marks was examined

A. Experimental Conditions

### Example 1

The needle mark transfer sheet 51 made of the polyimide resin having the characteristic illustrated in FIG. 3 (PIAD (product name) manufactured by Arakawa Chemical Industries, Ltd.) was used. The cantilever type probes 31 were brought into contact with the needle mark transfer sheet 51 in a state where the temperature was adjusted to 25° C., and an image of obtained needle marks was captured. The diameter of the needle tip of each probe 31 was 15 μm, and three overdrive (O.D.) amounts of 10 μm, 20 μm, and 30 μm were performed. In addition, the O.D. amount refers to an amount of the thrust of the tip of a probe into the sheet, from the position where the tip of the probe is in contact with the sheet.

### Example 2

The same experiment as that of Example 1 was conducted, except that each probe 31 formed by a vertical needle with a square planar tip was brought into contact with the needle mark transfer sheet 51. The diameter of the needle tip of the probe 31 was 5 μm, and four O.D. amounts of 20 μm, 30 μm, 40 μm, and 50 μm were performed.

### Example 3

The same experiment as that of Example 1 was conducted, except that each probe 31 formed by a crown-shaped pogo pin with four tips were brought into contact with the needle mark transfer sheet 51. The diameter of the needle tip of the probe 31 was 80 μm, and the O.D. amount was 40 μm.

### Example 4

The same experiment as that of Example 1 was conducted, except that each probe 31 formed by a cobra pin provided with a curved portion in the middle of the pin body was brought into contact with the needle mark transfer sheet 51. The diameter of the needle tip of the probe 31 was 80 μm, and the O.D. amount was 80 μm.

### Comparative Example 1

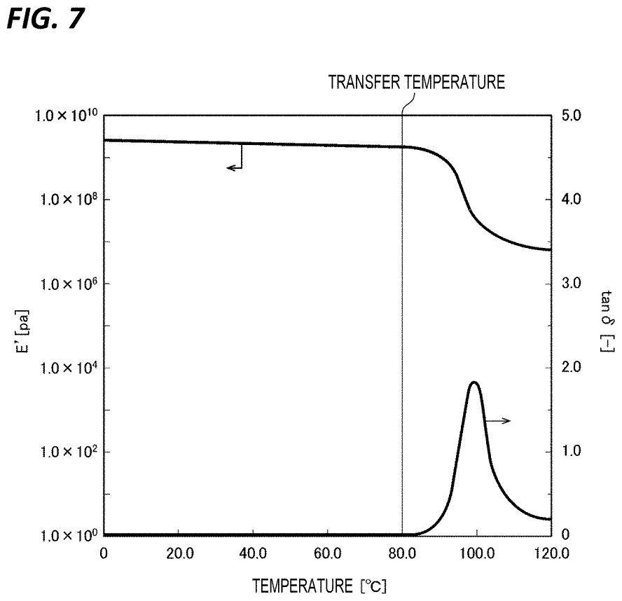

The needle mark transfer sheet 51 mainly made of the epoxy resin having the temperature characteristics of the storage elastic modulus E′ and the tan δ illustrated in FIG. 7 (Arakawa Chemical Co., COMPOSELAN (registered trademark) E) was heated to 80° C., the probes 31 having the same configuration as that of Example 1 were brought into contact with the needle mark transfer sheet 51, and an image of obtained needle marks was captured. In addition, the same experiment was conducted under a condition that the needle mark transfer sheet 51 was heated to 90° C. and 100° C., but there was no significant difference in the state of needle marks, as compared with the case where the needle mark transfer sheet 51 was heated to 80° C. Thus, only the result of 80° C. will be described (the same applies to Comparative Examples 2 to 4 below).

### Comparative Example 2

The same experiment as that of Comparative Example 1 was conducted, except that the same probes 31 as those of Example 2 were used (but three O.D. amounts of 50 μm, 60 μm, and 70 μm were performed).

### Comparative Example 3

The same experiment as that of Comparative Example 1 was conducted, except that the same probes 31 as those of Example 3 were used.

### Comparative Example 4

The same experiment as that of Comparative Example 1 was conducted, except that the same probes 31 as those of Example 4 were used.

B. Experiment Results

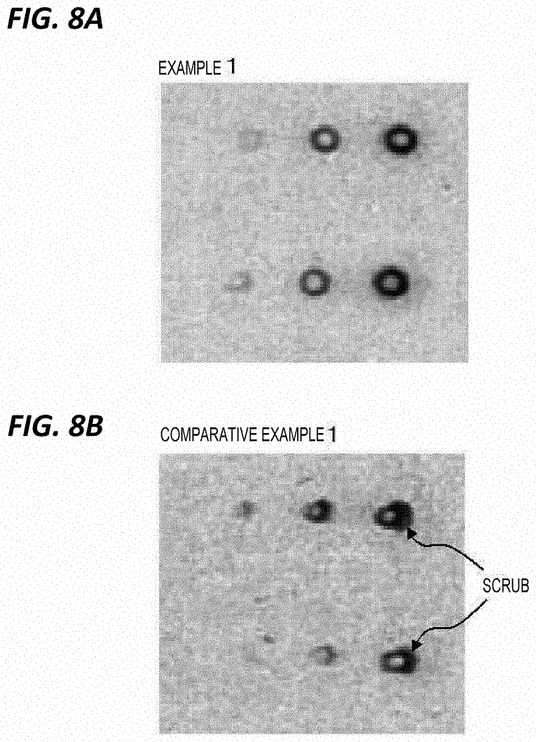

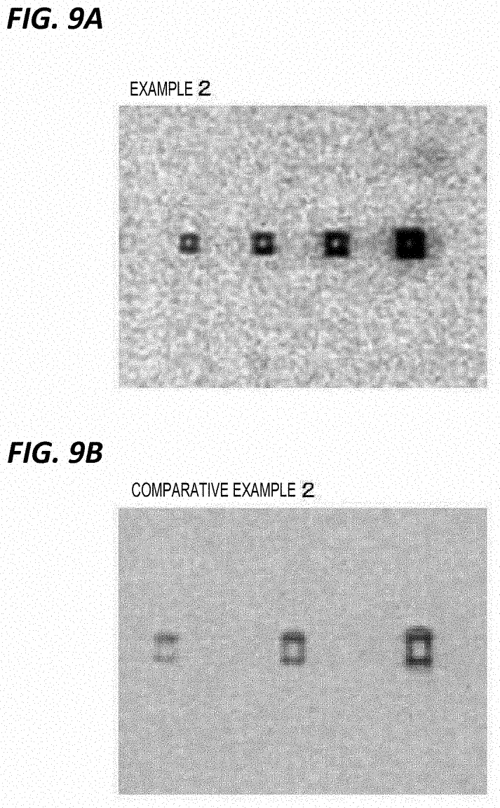

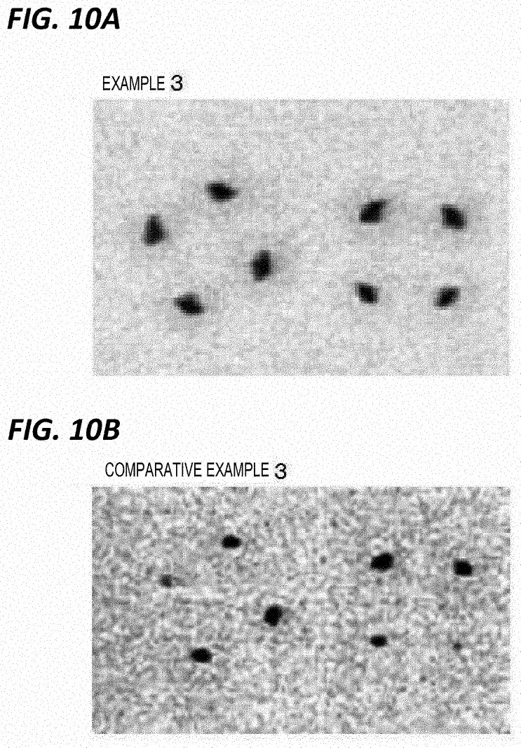

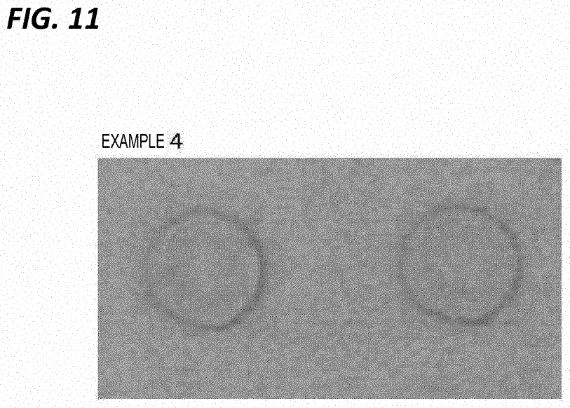

FIGS. 8A and 8B represent the results of the image capturing in Example 1 and Comparative Example 1, and FIGS. 9A and 9B represent the results of the image capturing in Example 2 and Comparative Example 2. Further, FIGS. 10A and 10B represent the results of the image capturing in Example 3 and Comparative Example 3, and FIG. 11 represents the results of the image capturing in Example 4.

According to the experiment results represented in FIGS. 8A, 9A, 10A, and 11, the probes 31 were able to transfer needle marks, irrespective of a type thereof, under the condition that the temperature of the needle mark transfer sheet 51 made of the polyimide resin was controlled to 25° C. For each cantilever type probe 31 (Example 1: FIG. 8A), each probe 31 which is a vertical needle with a square planar tip (Example 2: FIG. 9A), and each probe 31 which is a pogo pin with a crown-shaped tip (Example 3: FIG. 10A), clear needle marks were formed. Further, for each cobra pin of which needle mark is unlikely to be transferred due to its large diameter, it was identified that the needle mark could be transferred and recognized through an image (Example 4: FIG. 11).

The needle marks in the Comparative Examples (Comparative Examples 1 to 3: FIGS. 8B, 9B, and 10B) are relatively unclear, as compared to the Examples described above. Especially, in Comparative Example 1 using the cantilever type probe 31 of which the needle tip is inserted obliquely, scrubs occur due to the foam of the resin in the region into which the needle tip is inserted, and cause a factor that hinders the accurate position detection. Further, in the probe 31 which is a pogo pin, a needle mark could not be transferred.

According to the results of the transfer of needle marks to the needle mark transfer sheet 51 in Examples 1 to 4 and Comparative Examples 1 to 4 described above, it may be said that the technique of transferring the needle marks of the probes 31 using the needle mark transfer sheet 51 made of the polyimide resin is suitable for the inspection of the probes 31 using image data.

According to the present disclosure, since the needle mark transfer member to which needle marks are to be transferred by a contact with the probes includes the polyimide resin, clear needle marks may be transferred.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

Whai is claimed is:

1. A probe apparatus for performing an electrical measurement by bringing a probe provided on a probe card into contact with a substrate placed on a placement table, the probe apparatus comprising:
a transfer table provided with a needle mark transfer member to which a needle mark of the probe is transferred and configured to bring the probe into contact with the needle mark transfer member, instead of bringing the probe into contact with the substrate; and
a mover configured to move an arrangement position of at least one of the transfer table and the probe card between a contact position where the needle mark transfer member is brought into contact with the probe and a separation position where the needle mark transfer member is separated from the contact position,
wherein the needle mark transfer member includes a polyimide resin.

2. The probe apparatus according to claim 1, wherein the polyimide resin included in the needle mark transfer member has a thermo-plasticity, and the transfer table includes a heater configured to heat the needle mark transfer member to a temperature at which the polyimide resin is deformable accompanied by the contact with the probe.

3. The probe apparatus according to claim 2, wherein the heater heats the needle mark transfer member such that with respect to a peak temperature T_{P} at which a loss tangent (tan δ) of the polyimide resin peaks, a temperature t of the needle mark transfer member falls within a range of T_{P}<t<T_{P}+5° C.

4. The probe apparatus according to claim 2, wherein the transfer table includes a cooler configured to cool the needle mark transfer member to a temperature at which the needle mark is capable of remaining transferred to the needle mark transfer member after the contact with the probe.

5. The probe apparatus according to claim 4, wherein the cooler cools the needle mark transfer member such that a temperature t′ of the needle mark transfer member falls within a range of T_{P}−5° C.≤t′<T_{P} with respect to the peak temperature T_{P} at which the loss tangent (tan δ) of the polyimide resin peaks,

6. The probe apparatus according to claim 2, wherein the polyimide resin has a characteristic in which the peak temperature T_{P} at which the loss tangent (tan δ) of the polyimide resin peaks falls within a range of T_{S}±10° C. with respect to a temperature T_{S} of the substrate when the electrical measurement is performed using the probe.

7. The probe apparatus according to claim 6, wherein the temperature T_{S} of the substrate is within a range of 15° C. to 35° C.

8. The probe apparatus according to claim 6, wherein the polyimide resin has a characteristic in which the peak temperature T_{P} is adjusted to fall within a range of T_{S}±10° C. by adding a plasticizer.

9. The probe apparatus according to claim 1, further comprising:
a camera configured to capture an image of the needle mark transferred to the needle mark transfer member and detect a position of the probe.

10. A method of inspecting a probe of a probe apparatus that performs an electrical measurement by bringing a probe provided on a probe card into contact with a substrate, the method comprising:
transferring a needle mark of the probe by bringing the probe into contact with a needle mark transfer member that includes a polyimide resin.

11. The method according to claim 10, further comprising:
heating the needle mark transfer member to a temperature at which the polyimide resin is deformable accompanied by the contact with the probe, prior to the transferring the needle mark,
wherein the polyimide resin included in the needle mark transfer member has a thermo-plasticity.

12. The method according to claim 11, wherein in the heating the needle mark transfer member, the needle mark transfer member is heated such that a temperature t of the needle mark transfer member falls within a range of T_{P}<t≤T_{P}+5° C. with respect to a peak temperature T_{P} at which a loss tangent (tan δ) of the polyimide resin peaks.

13. The method according to claim 11, further comprising:
cooling the needle mark transfer member to a temperature at which the needle mark is capable of remaining transferred to the needle mark transfer member, after the transferring the needle mark.

14. The method according to claim 13, wherein in the cooling the needle mark transfer member, the needle mark transfer member is cooled such that a temperature t′ of the needle mark transfer member falls within a range of T_{P}−5° C.≤t′<T_{P} with respect to the peak temperature T_{P} at which the loss tangent (tan δ) of the polyimide resin peaks.

15. The method according to claim 11, wherein the polyimide resin has a characteristic in which the peak temperature T_{P} at which the loss tangent (tan δ) peaks falls within a range of T_{S}±10° C. with respect to a temperature T_{S} of the inspection target substrate when the electrical measurement is performed using the probe.

16. The method according to claim 15, wherein the polyimide resin has a characteristic in which the peak temperature T_{P} is adjusted to fall within a range of T_{S}±10° C. by adding a plasticizer.

17. The method according to claim 10, further comprising:
capturing an image of the needle mark transferred to the needle mark transfer member and detecting a position of the probe.

18. A non-transitory computer-readable storage medium storing a computer program used in a probe apparatus for performing an electrical measurement by bringing a probe provided on a probe card into contact with a substrate placed on a placement table and causes a computer to perform a process of inspecting the probe, the process comprising:
transferring a needle mark of the probe by bringing the probe into contact with a needle mark transfer member that includes a polyimide resin.
